(19) United States
(12) Patent Application Publication
(10) Pub. No.: US 2023/0371378 A1
(43) Pub. Date: Nov. 16, 2023

(54) TEMPERATURE SENSOR AND METHOD FOR PRODUCING A TEMPERATURE SENSOR

(71) Applicant: Danfoss A/S, Nordborg (DK)

(72) Inventors: Michael Taszarek, Nordborg (DK); Christian Eggert Mortensen, Sønderborg (DK); Sten Davidsen, Nordborg (DK); Mogens Steen Hansen, Nordborg (DK)

(21) Appl. No.: 18/314,448

(22) Filed: May 9, 2023

(30) Foreign Application Priority Data
May 10, 2022 (DE) 102022111698.0

(51) Int. Cl. H10N 10/01; G01K 7/02; H10N 10/80

(52) U.S. Cl. CPC H10N 10/01; G01K 7/02; H10N 10/80

(57) ABSTRACT

A method (100) for producing a temperature sensor (200), the method (100) comprising: providing (101) a cable (103), wherein electrical conductor portions (105) are protruding from an end of the cable (103); connecting (107) at least one temperature sensor element (109) to the electrical conductor portions (105) protruding from the cable (103); providing (111) a sensor capsule (113); connecting (115) a proximal end surface of the sensor capsule (113) to the end of the cable (103), so that the sensor capsule (113) surrounds the at least one temperature sensor element (109); providing (117) at least one drain opening (119) in the sensor capsule (113) near a connection area (121) of the cable (103) and the sensor capsule (113); filling (123) up a volume (125) of the sensor capsule (113) with a thermally conducting ceramic filler (127); connecting (129) an end cap (131) to a distal end surface (133) of the sensor capsule (113); sealing (135) the drain opening (119).

### CROSS-REFERENCE TO RELATED APPLICATION

This application claims foreign priority benefits under 35 U.S.C. § 119 from German Patent Application No. 102022111698.0, filed May 10, 2022, the content of which is hereby incorporated by reference in its entirety.

### TECHNICAL FIELD

The invention disclosed herein relates to a method for producing a temperature sensor, in particular to a high temperature sensor, and to a temperature sensor as set out in the accompanied claims.

### BACKGROUND

High temperature sensors, such as exhaust gas temperature sensors for combustion engines, for example, are exposed to harsh environmental conditions, e.g. in respect to temperatures of more than 600 degrees Celcius, corrosive environments, and vibration loads.

U.S. Pat. No. 7,982,580 B2 discloses a known sensor comprising a mineral insulated cable (MI cable), which consists of a stainless steel sheath filled with mineral insulting powder and a sensor portion. The sensor portion comprises a tubular element welded to the sheath of the MI cable and is closed by an end cap. The tubular element accommodates a temperature sensor element encapsulated in a thermally conducting ceramic filler.

It is a problem to ensure a homogeneous filling of a sensor portion with the ceramic filling material. If air bubbles are enclosed around the temperature sensor element, the lifetime of such sensors may be reduced, especially when exposed to vibrational loads, as the sensor element is not completely fixated within the ceramic filler, failures may occur due to breakage of wires.

### SUMMARY

It is therefore a task of the present invention to provide a temperature sensor with improved mechanical strength and lifetime.

For solving the above identified problem, it is provided, according to a first aspect of the present invention, a method for producing a temperature sensor. The method comprises providing a cable, wherein electrical conductor portions are protruding from an end of the cable, connecting at least one temperature sensor element to the electrical conductor portions protruding from the cable, providing a sensor capsule, connecting a proximal end surface of the sensor capsule to the end of the cable, so that the sensor capsule surrounds the at least one sensor element, providing at least one drain opening in the sensor capsule near a connection area of the cable and the sensor capsule, filling up the sensor capsule volume with a thermally conducting ceramic filler, connecting an end cap to a distal end surface of the sensor capsule, and sealing the drain opening.

In the context of the present invention, a temperature sensor element is an element configured to sense, i.e. to measure, a temperature. The temperature sensor element may be a resistance temperature detector (RTD) element or a thermocouple.

The present invention is based on the principle that at least one drain opening in a sensor capsule encapsulating a temperature sensor element is used to enable air enclosed in a thermally conducting ceramic filler filled in a sensor capsule, to escape from the sensor capsule before the ceramic filler hardens. Thus, the at least one drain opening provides for a dense and compact filling of the sensor capsule with the ceramic filler, such that the filling of the sensor capsule comprises only a very small amount of air bubbles or no air bubbles at all.

By minimizing the amount of air included in the ceramic filler filled in the sensor capsule, the contact surface between the at least one temperature sensor element arranged inside the sensor capsule and the ceramic filler is maximized, thereby increasing thermal flow from the ceramic filler to the at least one temperature sensor and providing for a mechanically stable hold of the at least one temperature sensor in the sensor capsule. In other words, the at least one temperature sensor is completely fixated in the sensor capsule by a homogenous ceramic filler.

According to an embodiment, the method further comprises curing the ceramic filler before the end cap is connected to the distal end surface of the sensor capsule.

Curing the ceramic filler may comprise a predetermined time for which the filled sensor capsule is left in a stable position or turned in a predetermined trajectory, in order to enable the air included in the ceramic filler to escape through the at least one drain opening and to enable the ceramic filler to harden. Additionally, curing may comprise a heating procedure in an oven, for example.

Alternatively, or additionally, curing the ceramic filler may comprise inducing vibration loads with a predetermined frequency in the ceramic filler in order to force air included in the ceramic filler to escape from the sensor capsule.

According to an embodiment, the at least one temperature sensor element is welded, in particular laser welded, to the electrical conductor portions protruding from the cable. Alternatively, the temperature sensor element may be created by connecting two different conductors, such as Ni and NiCr conductors, in a welding joint.

Welding the temperature sensor element to the electrical conductor portions provides for a strong and reliable connection between the temperature sensor element and the electrical conductor portions. By using laser welding, the welding spots can be set precisely, thereby ensuring electrical connectivity between the temperature sensor element and the electrical conductor portions.

According to an embodiment, the thermally conducting ceramic filler is a ceramic cement potting material.

Ceramic cement potting material is both, mechanically stable and thermally conductive. Thus, ceramic cement potting material is an ideal material for filling the sensor capsule and fixating the temperature sensor element in the sensor capsule.

According to an embodiment, the proximal end surface of the sensor capsule is welded to the end of the cable. Preferably, the sensor capsule is a metal part.

For welding the metal sensor capsule to the cable, the cable may be a mineral insulated cable having a metal sheath. Accordingly, after welding, the cable and the sensor capsule form a monolithic composition.

According to an embodiment, the end cap is welded to the distal end surface of the sensor capsule. Preferably, the end cap is a metal part.

By welding an end cap on the distal end surface of the sensor capsule, the capsule is closed and sealed.

According to an embodiment, the cable is a mineral insulated cable.

A mineral insulated cable may comprise a metal sheath and electrical conductors arranged within the sheath, where the electrical conductors are embedded in insulating mineral material, such as magnesia, for example.

According to an embodiment, the at least one temperature sensor element comprises platinum wires.

Platinum wires provide for a reliable connection between the temperature sensor element, such as thinfilm or wire-wound platinum structures, and the electrical conductor portions of the MI cable.

According to an embodiment, providing at least one drain opening in the sensor capsule comprises drilling at least one hole in a wall of the sensor capsule, or forming a recess in the distal end of the sensor capsule, or forming a circumferentially incomplete welding seam in a first welding operation, when connecting the sensor capsule to the cable, so that a small gap section is formed in an interface between the end of the cable and the proximal end of the sensor capsule, and sealing the drain opening in a second welding operation after filling up the sensor capsule volume with ceramic cement potting material.

While drilling a hole or forming a recess in the sensor capsule is a time effective way of providing the drain opening, a two-stepped welding process provides for a seamless sealing that is stable and fluid tight.

According to a second aspect, the present inventions relates to a temperature sensor produced by an embodiment of the method disclosed herein. The temperature sensor may be a temperature sensor for an exhaust system of a combustion engine.

Since the method disclosed herein leads to a very dense and homogeneous ceramic filler material, the temperature sensor disclosed herein has such a dense and homogeneous ceramic filler surrounding its temperature sensor element that has very little or even no air bubbles included. Thus, the temperature sensor is very stable and precise.

### BRIEF DESCRIPTION OF THE DRAWINGS

Hereinafter, preferred embodiments of the present disclosure will be described with reference to the accompanying drawings. In the drawings:

FIG. 1 shows an embodiment of a method for producing a temperature sensor according to the present invention.

### DETAILED DESCRIPTION

First, it should be understood by those skilled in the art that these embodiments are only used to explain the technical principles of the present disclosure, and are not intended to limit the scope of protection of the present disclosure. For example, although the following embodiments are explained in conjunction with an apparatus, this is not limitative. The technical solutions of the present disclosure are also applicable to other devices. Such a change to application object does not deviate from the principle and scope of the present disclosure.

In addition, it should also be noted that in the description of the present disclosure, unless otherwise clearly specified and defined, terms “dispose”, “install”, “connect” and “connection” should be understood in a broad sense; for example, the connection may be a fixed connection, or may also be a detachable connection, or an integral connection; it may be a mechanical connection, or an electrical connection; it may be a direct connection, or an indirect connection implemented through an intermediate medium, or it may be an internal communication between two elements. For those skilled in the art, the specific meaning of the above terms in the present disclosure can be understood according to specific situations.

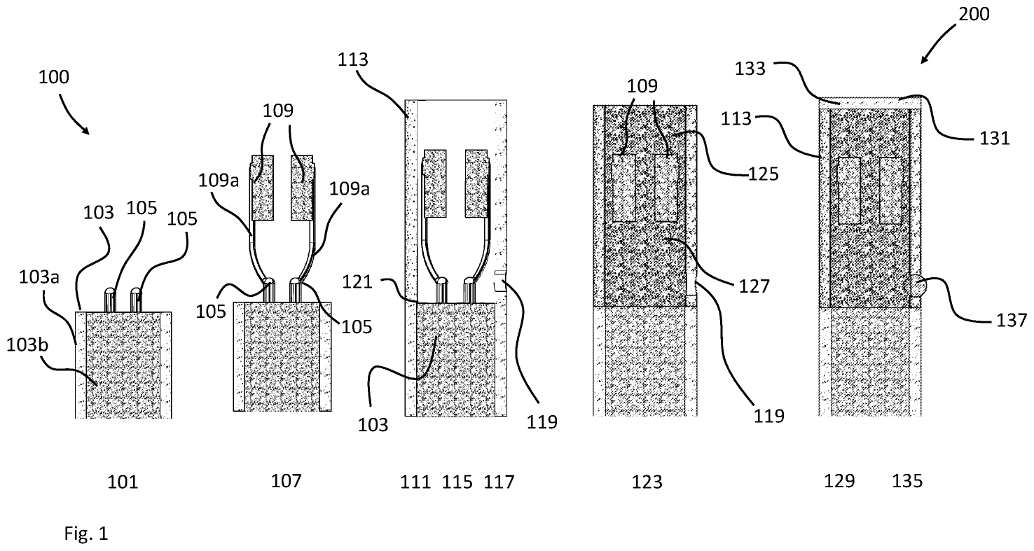

In FIG. 1, a method 100 for producing a temperature sensor 200 is shown.

The method 100 comprises a first provisioning step 101, in which a cable 103, such as a MI cable comprising an outer metal sheath filled with mineral material 103b for example, is provided, wherein electrical conductor portions 105 are protruding from an end of the cable.

Further, the method 100 comprises a connection step 107, in which at least one temperature sensor element 109 is connected to the electrical conductor portions 105 protruding from the cable 103. According to an example, the connection step may comprise connecting two different electrical conductors, such as Ni and NiCr conductors, in a welding joint to form a thermocouple. In particular, platinum wires 109a may be used as connection elements connections the at least one temperature sensor element 109 to the electrical conductor portions 105.

Further, the method 100 comprises a second provisioning step 111, in which a metal sensor capsule 113 is provided. The sensor capsule 113 is connected with its proximal end surface to the end of the cable 103, preferably to the end surface of the metal sheath 103a, so that the sensor capsule 113 surrounds the at least one temperature sensor element 109, in a first connection step 115.

Further, the method 100 comprises a third provisioning step 117, in which at least one drain opening 119 is provided in the sensor capsule 113 near a connection area 121 of the cable 103 and the sensor capsule 113. According to an example, the connection area 121 is located between the sensor capsule 113 and the metal sheath 103a of the cable 103, such that the drain opening 119 forms a small gap between the sensor capsule 113 and the cable 103, which is sealed after filling step 123 by a welding process, for example. Alternatively, the drain opening 119 may be formed in the sensor capsule 113 before the sensor capsule 113 is connected to the cable 103, such that the sensor capsule 113 can be pre-fabricated including the drain opening 119. In this case, the drain opening 119 may be formed as a hole in the wall or as a recess in a proximal end surface of the of the sensor capsule 113.

Further, the method 100 comprises filling and curing step 123, in which a volume 125 of the sensor capsule 113 is filled with a thermally conducting ceramic filler 127 and subsequently cured in a curing process with a predetermined temperature profile, for example.

Further, the method 100 comprises a second connection step 129, in which an end cap 131 is connected to a distal end surface 133 of the sensor capsule 113.

Further, the method 100 comprises a sealing step 135, in which the drain opening 119 is sealed by a sealing 137. The sealing 137 may comprise a separate sealing element pressed and/or welded into the drain opening, or may comprise melted sensor capsule or cable sheath material.

What is claimed is:

1. A method for producing a temperature sensor, the method comprising:
providing a cable, wherein conducting electrical conductor portions are protruding from an end of the cable,
connecting at least one temperature sensor element to the electrical conductor portions protruding from the cable,
providing a sensor capsule,
connecting a proximal end surface of the sensor capsule to the end of the cable, so that the sensor capsule surrounds the at least one temperature sensor element,
providing at least one drain opening in the sensor capsule near a connection area of the cable and the sensor capsule,
filling up a volume of the sensor capsule with a thermally conducting ceramic filler,
connecting an end cap to a distal end surface of the sensor capsule,
sealing the drain opening.

2. The method according to claim 1, the method further comprising:
curing the ceramic filler before the end cap is connected to the distal end surface of the sensor capsule.

3. The method according to claim 1,
wherein the at least one temperature sensor element is welded, in particular laser welded, to the electrical conductor portions protruding from the cable.

4. The method according to claim 1,
wherein connecting the at least one temperature sensor element to the electrical conductor portions protruding from the cable comprises connecting two different electrical conductors.

5. The method according to claim 1,
wherein the thermally conducting ceramic filler is a ceramic cement potting material.

6. The method according to claim 1,
wherein the proximal end surface of the sensor capsule is welded to the end of the cable.

7. The method according to claim 1,
wherein the end cap is welded to the distal end surface of the sensor capsule.

8. The method according to claim 1,
wherein the cable is a mineral insulated cable.

9. The method according to claim 1,
wherein the at least one temperature sensor element comprises platinum wires.

10. The method according to claim 1,
wherein providing at least one drain opening in the sensor capsule comprises:
drilling at least one hole in a wall of the sensor capsule, or
forming a recess in the distal end of the sensor capsule, or
forming a circumferentially incomplete welding seam in a first welding operation, when connecting to the cable, so that a small gap section is formed in an interface between the end of the cable and the proximal end of the sensor capsule, and
sealing the drain opening in a second welding operation after filling up the sensor capsule volume with the ceramic filler.

11. A temperature sensor produced by the method according to claim 1.

12. The method according to claim 2,
wherein the at least one temperature sensor element is welded, in particular laser welded, to the electrical conductor portions protruding from the cable.

13. The method according to claim 2,
wherein connecting the at least one temperature sensor element to the electrical conductor portions protruding from the cable comprises connecting two different electrical conductors.

14. The method according to claim 3,
wherein connecting the at least one temperature sensor element to the electrical conductor portions protruding from the cable comprises connecting two different electrical conductors.

15. The method according to claim 2,
wherein the thermally conducting ceramic filler is a ceramic cement potting material.

16. The method according to claim 3,
wherein the thermally conducting ceramic filler is a ceramic cement potting material.

17. The method according to claim 4,
wherein the thermally conducting ceramic filler is a ceramic cement potting material.
